(19) United States
(12) Patent Application Publication
(10) Pub. No.: US 2019/0153582 A1
(43) Pub. Date: May 23, 2019

(54) SPUTTERING APPARATUS AND METHOD FOR MANUFACTURING FILM

(71) Applicant: CANON KABUSHIKI KAISHA, Tokyo (JP)

(72) Inventor: Soya Todo, Sendai-shi (JP)

(21) Appl. No.: 16/184,306

(22) Filed: Nov. 8, 2018

(30) Foreign Application Priority Data
Nov. 21, 2017 (JP) 2017-223897

(51) Int. Cl. C23C 14/00; H01J 37/32; C23C 14/54; C23C 14/35

(52) U.S. Cl. CPC C23C 14/0042; H01J 37/32449; H01J 37/3405; C23C 14/54; C23C 14/35; C23C 14/0094

(57) ABSTRACT

An apparatus includes a chamber, a reactive gas supply unit, an inert gas supply unit, a power source, a light reception unit, and a control unit configured to control at least one of a flow rate of the reactive gas and a flow rate of inert gas in such a manner that an intensity of the light approaches a target light intensity with use of a predetermined function in which an output of the power source in a compound mode and an output of the power source in a transition mode, and a film formation speed are associated with each other.

### BACKGROUND OF THE INVENTION

### Field of the Invention

The aspect of the embodiments relates to a sputtering apparatus and a method for manufacturing a film by sputtering.

### Description of the Related Art

Sputtering is utilized for the purpose of forming a film on various film formation objects, such as an optical thin film and a semiconductor integrated circuit. Methods for sputtering that forms a compound thin film on the film formation object include high-frequency sputtering, which sputters a compound target by a high-frequency electric discharge, and reactive sputtering, which sputters a metal target by introducing reactive gas into a chamber. In recent years, the reactive sputtering has been prevailing due to demands for a cost reduction and improvement of productivity.

It is known that, for the reactive sputtering, there are three reaction modes for forming films at different speeds and with different film qualities from one another. The three reaction modes are called a metal mode, a transition mode, and a compound mode. The compound mode is also called a reactive mode. States of surfaces of the target and the film formation object are changed and the reaction mode is also changed depending on, for example, a flow rate of the reactive gas introduced into the chamber. The reaction modes capable of forming the compound thin film are the compound mode and the transition mode. The compound mode is a stable reaction mode, but a film formation speed is slow therein. The transition mode achieves a relatively high film formation speed, but is such an unstable reaction mode that the film formation speed is largely changed even due to a slight change in a process condition such as the flow rate of the reactive gas.

Plasma emission monitor control (PEM control) is known as a method for controlling the film formation in the transition mode. The PEM control is a method that stably forms the film by monitoring light emission of plasma and performing feedback control such as proportional-integral-derivative (PID) control of the monitored value.

Japanese Patent Application Laid-Open No. 2006-28624 proposes a method that controls the reactive gas by the PEM control with use of a niobium target and manufactures a niobium oxide thin film by the reactive sputtering method.

When the film is formed in the transition mode by the PEM control, it is important to correctly monitor the film formation speed to acquire a thin film having a desired film thickness. However, it has been found out that, if the film formation is continuously carried out onto a large number of film formation objects over a long period of time, a corresponding relationship between the light emission of the plasma and a voltage applied to the target, and the film formation speed is largely changed due to influences of consumption of the target, film deposition onto an inner side of the chamber, and the like. Therefore, the film formation speed cannot be correctly monitored only by the light emission of the plasma and the voltage applied to the target during the film formation.

### SUMMARY OF THE INVENTION

According to an aspect of the embodiments, an apparatus includes a chamber configured such that a film formation object and a target are disposed therein, a reactive gas supply unit configured to supply reactive gas into the chamber, an inert gas supply unit configured to supply inert gas into the chamber, a power source configured to supply power to the target to generate plasma inside the chamber to cause an ion of the inert gas in the plasma to collide with the target, a light reception unit configured to receive light emitted from the plasma, and a control unit configured to control at least one of a flow rate of the reactive gas and a flow rate of the inert gas such that an intensity of the light approaches a target light intensity with use of a predetermined function in which an output of the power source in a compound mode and an output of the power source in a transition mode, and a film formation speed are associated with each other.

Further features of the present disclosure will become apparent from the following description of exemplary embodiments with reference to the attached drawings.

### BRIEF DESCRIPTION OF THE DRAWINGS

FIG. 1 illustrates a sputtering apparatus according to an exemplary embodiment.

FIG. 2A is a block diagram illustrating a configuration of a controller according to the exemplary embodiment. FIG. 2B is a block diagram illustrating functions of a central processing unit (CPU) of the controller according to the exemplary embodiment.

FIGS. 3A and 3B each illustrate a relationship of a film formation speed to a flow rate of reactive gas.

FIG. 4 is a flowchart illustrating a method for manufacturing a film according to the exemplary embodiment.

FIG. 5 is a flowchart illustrating a method for generating an equation F according to the exemplary embodiment.

FIG. 6A illustrates reproducibility of a film thickness according to an example 1.

FIG. 6B illustrates reproducibility of the film thickness according to a comparative example 1.

### DESCRIPTION OF THE EMBODIMENTS

In the following description, an exemplary embodiment for implementing the present disclosure will be described in detail with reference to the drawings.

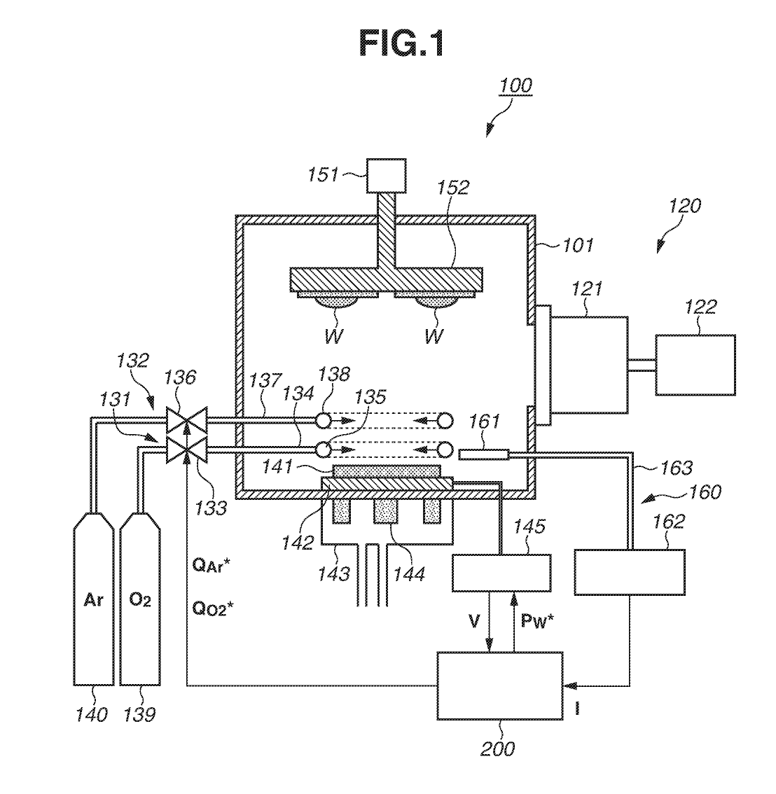

FIG. 1 illustrates a sputtering apparatus according to a first exemplary embodiment. A sputtering apparatus 100 is a direct-current (DC) magnetron sputtering apparatus in the present exemplary embodiment. The sputtering apparatus 100 forms a thin film such as an anti-reflective film on a surface of a lens substrate W, which is a film formation object, by the reactive sputtering. The thin film is formed on the surface of the lens substrate W by the sputtering apparatus 100, as a result of which a film-formed product such as a lens as a finished product or an intermediate product of the lens is manufactured.

The sputtering apparatus 100 includes a chamber depressurized to a vacuum, i.e., a vacuum chamber 101, and a controller 200. The vacuum chamber 101 is evacuated by an evacuation mechanism 120 including a turbo-molecular pump 121 and a roughing pump 122, and is depressurized to a predetermined pressure and kept at it. An ultimate pressure in the vacuum chamber 101 is measured by a not-illustrated Pirani gauge or ionization gauge, and a pressure at the time of the film formation is measured by a not-illustrated diaphragm gauge.

A target 141 and the lens substrates W are disposed inside the vacuum chamber 101. The target 141 is held on a backing plate 142 disposed inside the vacuum chamber 101. The target 141 is a film material such as metal, and is, for example, silicon (Si).

The lens substrates W are held on a holder 152 disposed at a position facing the target 141. The holder 152 is driven rotationally around a rotational shaft by a drive device 151. The holder 152 can hold a plurality of lens substrates W, and causes revolutions of the plurality of lens substrates W around the rotational shaft by rotating itself around the rotational shaft.

A reactive gas supply unit 131 is connected to the vacuum chamber 101. The reactive gas supply unit 131 includes a flow rate adjuster 133 that adjusts a flow rate of reactive gas, and a gas introduction line 134 that introduces the reactive gas into the vacuum chamber 101. In other words, the flow rate adjuster 133 and the vacuum chamber 101 are connected to each other via the gas introduction line 134. A gas cylinder 139, which is a supply source of the reactive gas, is connected to the flow rate adjuster 133.

The flow rate adjuster 133 is a mass flow controller, and adjusts the flow rate of the reactive gas to be output to the gas introduction line 134 according to a target flow rate Q_{O2}* of the reactive gas that is input from the controller 200. The gas introduction line 134 includes a ring-shaped tube 135 disposed between the lens substrates W and the target 141 and near the target 141, and the reactive gas is injected evenly from a not-illustrated plurality of holes provided on an inner side of the tube 135 at even intervals. The reactive gas is supplied into the vacuum chamber 101 by the reactive gas supply unit 131 configured in this manner. The reactive gas is gas for forming compound films on the lens substrates W. In a case where the formed film is an oxide film, such as silicon dioxide (SiO₂), the reactive gas is oxygen (O₂) gas.

Further, an inert gas supply unit 132 is connected to the vacuum chamber 101. The inert gas supply unit 132 includes a flow rate adjuster 136 that adjusts a flow rate of inert gas, and a gas introduction line 137 that introduces the inert gas controlled at an adjusted flow rate into the vacuum chamber 101. In other words, the flow rate adjuster 136 and the vacuum chamber 101 are connected to each other via the gas introduction line 137. A gas cylinder 140, which is a supply source of the inert gas, is connected to the flow rate adjuster 136. The flow rate adjuster 136 is a mass flow controller, and adjusts the flow rate of the inert gas to be output to the gas introduction line 137 according to a target flow rate Q_{Ar}* of the inert gas that is input from the controller 200. The gas introduction line 137 includes a ring-shaped tube 138 disposed between the lens substrates W and the target 141 and near the target 141, and the inert gas is injected evenly from a not-illustrated plurality of holes provided on an inner side of the tube 138 at even intervals. The inert gas is supplied into the vacuum chamber 101 by the inert gas supply unit 132 configured in this manner. The inert gas is gas for generating plasma in the vacuum chamber 101, and is, for example, argon (Ar) gas.

A power source 145, which is a sputter power source, is connected to the target 141 via the backing plate 142. This power source 145 is a direct-current pulse power source, and operates with the target 141, i.e., the backing plate 142 serving as a cathode, and the vacuum chamber 101 serving as an anode. Therefore, the plasma is generated near the target 141 by application of a negative voltage to the target 141.

A cooling system 143 is disposed near a back surface of the baking plate 142. The cooling system 143 cools down the target 141 with use of cooling water to prevent or cut down an increase in a temperature of the target 141. Magnets 144 are installed near the target 141, i.e., the back surface of the backing plate 142, and therefore low-voltage and high-density plasma can be generated.

When the reactive gas is introduced into the vacuum chamber 101 by the flow rate adjuster 133, the reactive gas reacts with atoms of the target 141, by which a compound film is formed on the surface of the target 141. When output power of the power source 145 is supplied to the target 141 during the introduction of the inert gas, an electric discharge occurs inside the vacuum chamber 101, more specifically, near the target 141. Due to the occurrence of the electric discharge, the inert gas is ionized, i.e., the plasma is generated. Ions of the inert gas in the plasma collide with the target 141, and thereby the surface of the target 141 is sputtered. Particles sputtered by the ions of the inert gas are released from the target 141, and form the compound films on the lens substrates W.

The sputtering apparatus 100 includes a light reception unit 160 that receives light emitted from the plasma. The light reception unit 160 includes a collimator 161 and a spectrometer 162. The collimator 161 and the spectrometer 162 are connected to each other via an optical fiber 163. The collimator 161 is disposed inside the vacuum chamber 101 and near the surface of the target 141 in an orientation in parallel with the surface of the target 141, and collects the plasma light.

The spectrometer 162 includes a diffractive grating and a charge coupled device (CCD) sensor, and makes a spectrophotometric analysis of the plasma light acquired from the collimator 161 via the optical fiber 163 to transmit, to the controller 200, information indicating a spectral intensity of the light, i.e., an intensity I of the light per predetermined wavelength in the form of an electric signal. The light reception unit 160 may be configured to measure the intensity I of the light with use of a band pass filter (BPF) and a photomultiplier tube (PMT) instead of the spectrometer 162. The controller 200 acquires the information indicating the intensity I of the light from the spectrometer 162 of the light reception unit 160 via a signal line in the form of the electric signal.

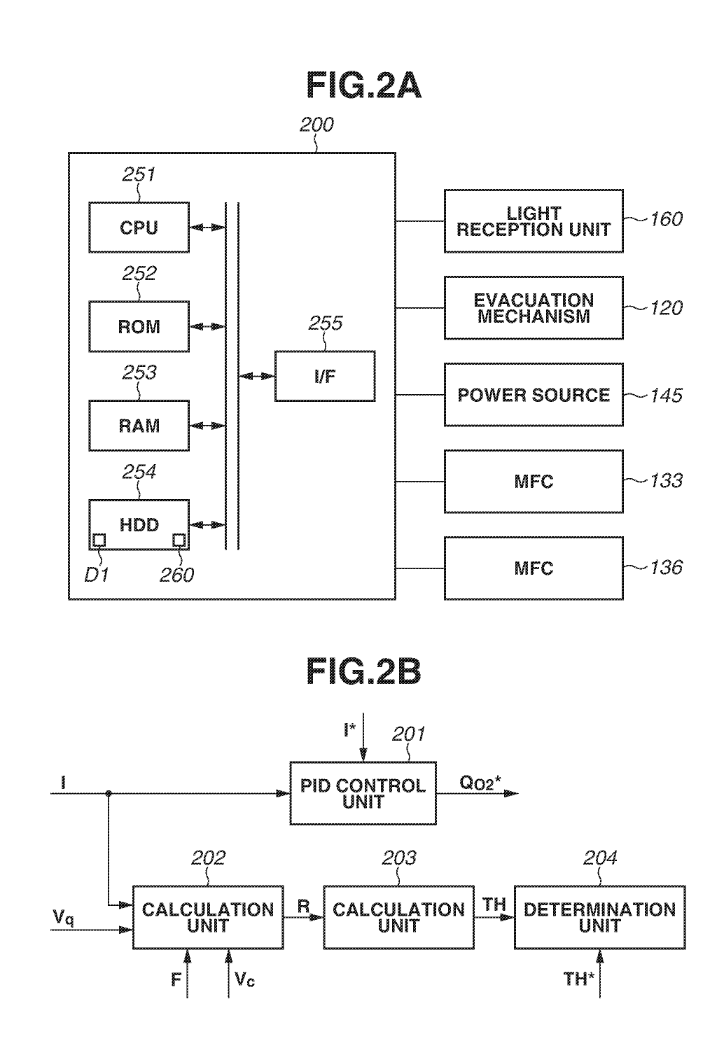

FIG. 2A is a block diagram illustrating a configuration of the controller 200 according to the present exemplary embodiment. The controller 200 includes a central processing unit (CPU) 251 as a control unit. Further, the controller 200 includes a read only memory (ROM) 252, a random access memory (RAM) 253, and a hard disk drive (HDD) 254. Further, the controller 200 includes an interface 255.

The ROM 252, the RAM 253, the HDD 254, and the interface 255 are connected to the CPU 251 via a bus. A basic program for causing the CPU 251 to operate is stored in the ROM 252.

The RAM 253 is a storage device temporarily storing therein various kinds of data, such as a result of calculation processing by the CPU 251. The HDD 254 is a storage device storing therein the result of the calculation processing by the CPU 251, setting data acquired from outside, and the like, and also functions to record therein a program 260 for causing the CPU 251 to perform various kinds of calculation processing that will be described below, i.e., each process in a method for manufacturing the film. Further, the HDD 254 stores therein information indicating a target light intensity I*, target power P_{W}* of the power source 145, a target flow rate Q_{Ar}* of the inert gas, and a target film thickness TH*. Further, the HDD 254 stores therein a predetermined function D1 in which a power source voltage Vc in the compound mode and a power source voltage Vq in the transition mode, and a film formation speed are associated with each other, and a latest value Vc of the power source voltage in the compound mode.

FIG. 2B is a block diagram illustrating functions of the CPU 251 of the controller 200. The CPU 251 functions as a PID control unit 201, a calculation unit 202, a calculation unit 203, and a determination unit 204 illustrated in FIG. 2B by operating according to the program 260 recorded in the HDD 254.

The light reception unit 160, the evacuation mechanism 120, the power source 145, and the flow rate adjusters (mass flow controllers (MFCs)) 133 and 136 are connected to the interface 255, and the interface 255 receives inputs of the information indicating the light intensity I and information indicating a film formation condition in the form of electric signals. The information indicating the film formation condition is information indicating a speed of the evacuation by the evacuation mechanism 120, information indicating an output of the power source 145, information indicating a flow rate Q_{O2} of the reactive gas by the flow rate adjuster 133, and information indicating a flow rate Q_{Ar} of the inert gas by the flow rate adjuster 136. The information indicating the output of the power source 145 is at least one piece of information among an output voltage, an output current, and output power of the power source 145, and is information indicating an output voltage V in the present exemplary embodiment. The interface 255 converts the input electric signal into an electric signal processable by the CPU 251 as necessary.

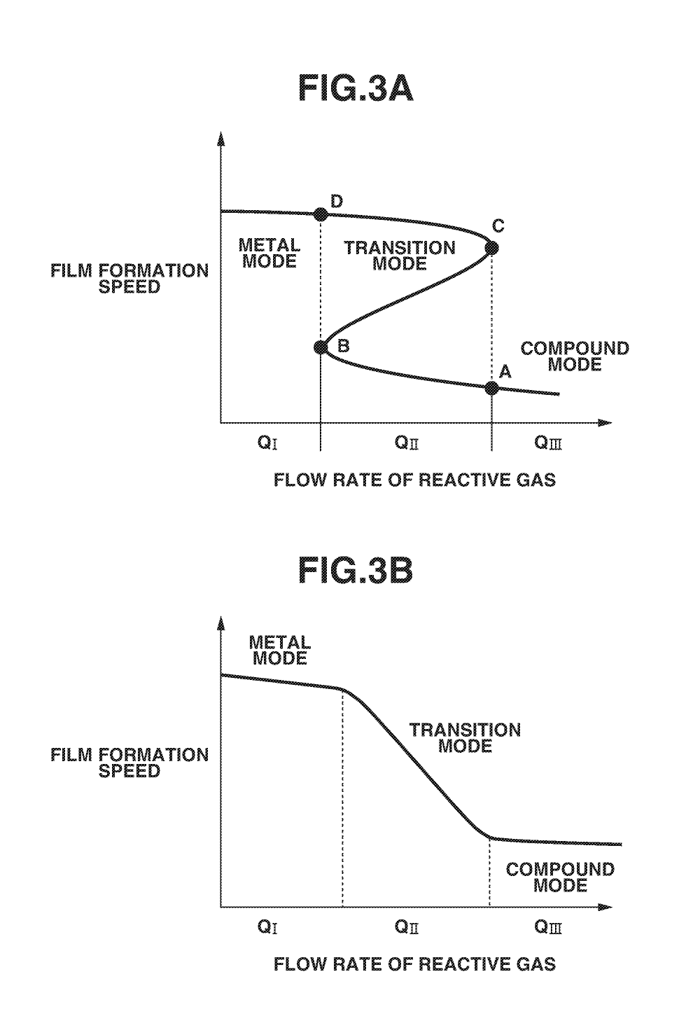

FIGS. 3A and 3B each illustrate a relationship of the film formation speed to the flow rate Q_{O2} of the reactive gas. The relationship between the flow rate Q_{O2} of the reactive gas and the film formation speed in the reactive sputtering will be described with reference to FIGS. 3A and 3B. For the reactive sputtering, there are the three reaction modes that form the film at different speeds and lead to acquisition of different film qualities from one another, as states of the surface of the target 141. The three reaction modes are the metal mode, the compound mode, and the transition mode between the metal mode and the compound mode. A reason why there are these three modes is that the reactive gas reacts with the atoms on the surface of the target 141 and the surface of the target 141 is covered with the compounds.

The compound mode is a gas flow rate region Q_{III} in FIGS. 3A and 3B, and is such a state that the reactive gas is present by an amount sufficient to maintain the compounds on the surface of the target 141. In the case of this compound mode, the reaction advances sufficiently and a compound satisfying a stoichiometric proportion can be easily acquired, but the film formation speed is slow therein compared to the other two states. A binding force in the compound film on the surface of the target 141 and a binding force between the target material and the compound film are stronger than a binding force of the target material such as metal. Higher energy is used to cut these bindings and sputter the target 141 to emit the compounds out therefrom, so that a sputter rate of the compounds falls below a sputter rate of the metal, as a result of which the film formation speed slows down.

The metal mode is a gas flow rate region Q₁ in FIGS. 3A and 3B, and is such a state that the reactive gas is not present by the amount sufficient to cover the surface of the target 141 with the compounds, and the metal accounts for a larger percentage of the surface of the target 141 than the compounds. As a result, the metal mode achieves a higher film formation speed than the compound mode, but results in acquisition of an insufficiently reacted metallic film as the formed thin film. Therefore, the thin film formed in the metal mode often fails to realize a required film function.

The transition mode is a gas flow rate region Q_{II} in FIGS. 3A and 3B, and is a reaction mode in which the reactive gas is present by an amount corresponding to the middle between the compound mode and the metal mode. The compounds are formed on a part of the surface of the target 141, and both the compounds and the metal exist on the surface of the target 141. Therefore, the transition mode achieves a higher film formation speed than the compound mode, but is an unstable reaction mode.

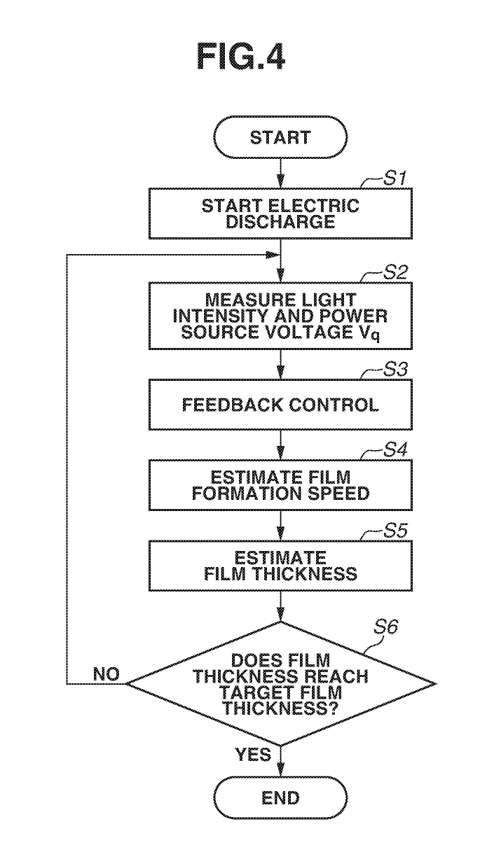

In the first exemplary embodiment, the film is formed by the plasma emission monitor control (PEM control) in the transition mode capable of achieving the higher film formation speed than the compound mode. In the following description, the PEM control by the controller 200, i.e., the CPU 251 will be specifically described. FIG. 4 is a flowchart illustrating the method for manufacturing the thin film according to the present exemplary embodiment.

In step S1, the CPU 251 outputs the instruction values Q_{O2}* and Q_{Ar}* to the flow rate adjusters 133 and 136 to control the flow rate Q_{O2} of the reactive gas and the flow rate Q_{Ar} of the inert gas, respectively, and also outputs the instruction value Pw* to the power source 145 to control the power to be supplied to the target 141, thereby starting the electric discharge.

In step S2, the CPU 251 periodically acquires the information indicating the spectral intensity of the plasma light, i.e., the information indicating the intensity I of the light from the light reception unit 160, and acquires the output voltage Vq of the power source 145. The CPU 251 measures the intensity I of the light and the output voltage Vq of the power source 145 every time a predetermined period has elapsed. The predetermined period is, for example, a period of 50 [msec].

In the first exemplary embodiment, a ratio of light intensities I_{Si}/I_{Ar} between an intensity I_{Si} of light emitted from the material of the target 141 and an intensity I_{Ar} of light emitted from the inert gas is used as the intensity I of the light. The CPU 251 acquires the ratio of light intensities between the intensity I_{Si} of the light emitted from the material of the target 141 and the intensity I_{Ar} of the light emitted from the inert gas, i.e., I, from the information indicating the spectral intensity of the plasma light received by the light reception unit 160.

In step S3, the CPU 251 functions as the PID control unit 201, and calculates a feedback amount in such a manner that the intensity I of the light approaches the target light intensity I* stored in the HDD 254 and converts the calculated feedback amount into a control signal. In the present exemplary embodiment, the feedback amount is the target flow rate Q_{O2}*. The CPU 251 transmits the control signal indicating the target flow rate Q_{O2}* to the flow rate adjuster 133, thereby controlling the flow rate Q_{O2} of the reactive gas. The proportional-integral-derivative (PID) control is used as an algorithm of the feedback control by the CPU 251.

As illustrated in FIG. 2A, the HDD 254 stores therein the predetermined function D1 in which the power source voltage Vc in the compound mode and the power source voltage Vq in the transition mode, and the film formation speed are associated with each other. In the present exemplary embodiment, the predetermined function D1 is expressed by a function F, which will be described below. The predetermined function D1 is a function generated by conducting an experiment or a simulation in advance. In step S4, the CPU 251 functions as the calculation unit 202 illustrated in FIG. 2B. The CPU 251 acquires an estimated film formation speed R corresponding to the intensity I of the light received by the light reception unit 160, the output voltage Vq of the power source 145, and the latest value Vc of the power source voltage in the compound mode that is stored in the HDD 254 with use of the equation F stored in the HDD 254. In other words, the CPU 251 estimates the film formation speed R.

Next, in step S5, the CPU 251 functions as the calculation unit 203 illustrated in FIG. 2B, and acquires an estimated film thickness TH from the film formation speed R estimated in step S3. In other words, the CPU 251 estimates the film thickness TH. A method for estimating the film thickness TH will be specifically described now. The CPU 251 acquires the film thickness TH by calculating a product of the film formation speed R estimated in step S4 and the above-described predetermined period, i.e., a time interval at which the intensity I of the light and the power source voltage Vq are acquired, and summing results of the calculation. In other words, the CPU 251 acquires the film thickness TH by integrating the estimated film formation speed R over time since a time point at which the electric discharge is started.

Further, in step S6, the CPU 251 functions as the determination unit 204, and compares the estimated film thickness TH calculated in step S5 and the target film thickness TH* stored in the HDD 254. If the estimated film thickness TH is thinner than the target film thickness TH* as a result of the comparison (NO in step S6), the processing returns to the process of step S2. If the estimated film thickness TH reaches the target film thickness TH* (YES in step S6), the CPU 251 transmits instruction values to the flow rate adjusters 133 and 136 and the power source 145 to stop the electric discharge, thereby ending the film formation. In this manner, the CPU 251 carries out the film formation until the estimated film thickness TH reaches the target film thickness TH*.

In the first exemplary embodiment, the predetermined function D1 is the function generated by conducting an experiment in advance. The predetermined function D1 is expressed by the function F, in which the power source voltage Vc in the compound mode and the power source voltage Vq in the transition mode that are stored in the HDD 254, and the film formation speed are associated with each other. A method for acquiring the function F will be described now.

A film formation speed rateq [nm/sec] in the transition mode can be considered to be expressed as indicated by the following equation (1).

$$rateq ∝ \frac{{P}_{q}}{{V}_{q}} \times Y \qquad ( 1 )$$

In this equation (1), Y represents a sputtering yield and P_{q} represents the power applied to the target 141 in the transition mode, and this means that the equation (1) is a product of the current applied to the target 141 and the sputtering yield in the transition mode. Generally, the sputtering yield increases as the voltage applied to the target 141 increases, and, further, increases as the reaction mode approaches the metal mode. The reaction mode can be expressed by oxide coverage θ of the surface of the target 141. The oxide coverage θ is such an amount that a value thereof becomes 1 when the reaction mode is the compound mode and 0 when the reaction mode is the metal mode. Therefore, the oxide coverage θ is in a correlative relationship with the voltage applied to the target 141. This correlative relationship can be considered to be such a relationship that the oxide coverage θ approaches 1 as the voltage applied to the target 141 approaches the power source voltage Vc.

The inventors have found out that the equation (1) can be expressed in the following manner, as a result of analyzing and earnestly studying the result of the experiment.

$$rateq ∝ \frac{{P}_{q}}{{V}_{q}} \times f ( {V}_{c} , {V}_{q} , \frac{{V}_{c}}{{V}_{q}} ) \qquad ( 2 )$$

The sputtering yield Y in the equation (1) can be expressed by a function f of Vc, Vq, and Vc/Vq. The inventors have found out that f can be approximated by a quadratic or lower-order function of Vc, Vq, and Vc/Vq, as a result of analyzing and earnestly studying the result of the experiment.

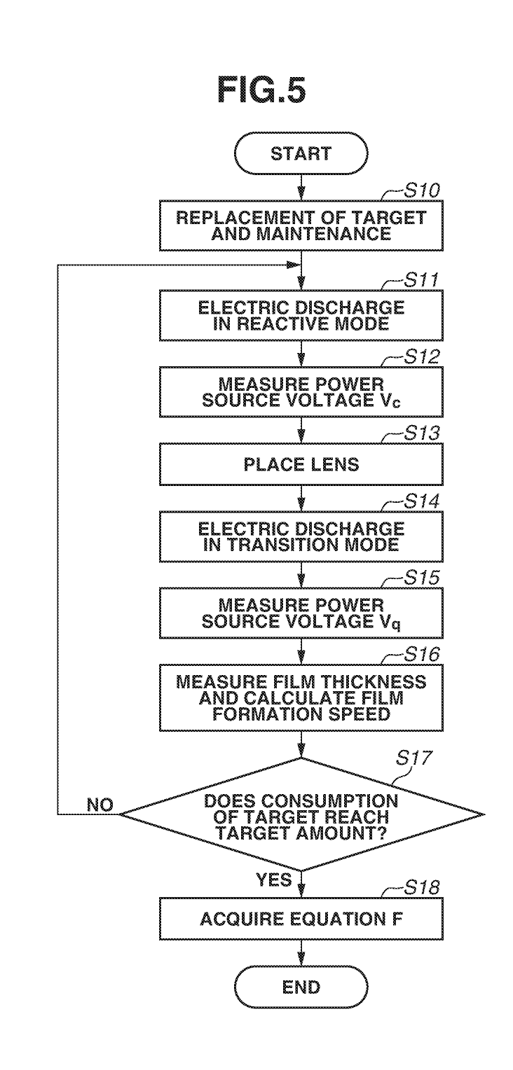

FIG. 5 is a flowchart illustrating the method for generating the equation F according to the present exemplary embodiment. In the following description, the method for generating the function F will be described in detail with reference to FIG. 5.

The function F is generated by conducting an experiment simulating continuous film formation over a long period of time with use of a film formation apparatus. First, in step S10, the condition of the film formation apparatus is stabilized by subjecting the vacuum chamber 101, the gas tubes 135 and 138, and the lens holder 152 to maintenance work, and replacing the target 141 with a new uneroded one.

Next, in step S11, the CPU 251 outputs the instruction values Q_{O2}* and Q_{Ar}* to the flow rate adjusters 133 and 136, thereby controlling the flow rate Q_{O2} of the reactive gas and the flow rate Q_{Ar} of the inert gas, respectively. Further, the CPU 251 outputs the instruction value Pw* to the power source 145 to control the power to be supplied to the target 141, thereby starting the electric discharge. In step S11, the instruction value Q_{O2}* is set in such a manner that the reaction mode is set to the compound mode. In step S12, the CPU 251 measures the power source voltage Vc in the compound mode.

Subsequently, in step S13, the lens substrates W are placed on the lens holder 152, and the inside of the vacuum chamber 101 is sufficiently depressurized by the evacuation mechanism 120. When the inside of the vacuum chamber 101 reaches or falls below a predetermined pressure, in step S14, the CPU 251 outputs the instruction value Pw* to the power source 145 to control the power to be supplied to the target 141, thereby starting the electric discharge. In step S14, the reaction mode is set to the transition mode with use of the PEM control. The PEM control calculates the feedback amount of the target flow rate Q_{O2}* in such a manner that the intensity I of the light received by the light reception unit 160 approaches the target light intensity I*, and controls the flow rate Q_{O2} of the reactive gas. In step S15, the CPU 251 measures the power source voltage Vq in the transition mode. After the electric discharge is ended, in step S16, the film thickness formed on the surface of each of the lens substrates W is evaluated by an evaluation apparatus that will be described below, and the film formation speed is calculated with use of an electric discharge time period measured by the CPU 251.

In step S17, the CPU 251 calculates a consumption amount of the target 141 from, for example, cumulative input power, and compares it with a target amount. If the consumption amount of the target 141 is smaller than the target amount as a result of the comparison (NO in step S17), the processing returns to the process of step S11, from which the CPU 251 sequentially acquires the combination of the power source voltage Vc in the compound mode, the power source voltage Vq in the transition mode, and the measured value of the film formation speed. If the consumption amount of the target 141 is the target amount or larger (YES in step S17), in step S18, the function F is acquired from the calculation, and then the experiment is ended.

The film thickness formed by the experiment is evaluated with use of the evaluation apparatus. The evaluation apparatus calculates the film thickness by measuring a reflectance at an incident angle of 5 degrees and within a wavelength range of 250 to 800 [nm] with use of Spectrophotometer U-4150 manufactured by Hitachi High-Technologies Corporation, and carrying out fitting based on a result of the above-described reflectance with use of calculation software. As the calculation software, examples usable for the calculation include software commercially available from various companies, besides Film Wizard provided by Scientific Computing International Company.

### EXAMPLE

### Example 1

The sputtering apparatus 100 used in the experiment carried out the film formation under the following conditions.

### Volume of Vacuum Chamber 101: 600 mm in Width×600 mm in Depth×800 mm in Height

### Evacuation Mechanism 120: Turbo-molecular Pump at 200 L/sec and Rotary Pump

### Power Source 145: DC Pulse Power Source

Shape of Target 141: φ8 inches in Diameter×5 mm in Thickness

### Material of Target 141: Si

### Inert Gas: Ar

### Reactive Gas: O₂

### Ultimate Pressure: 1×10⁻⁴ Pa

Lens Substrate W: Synthetic Quartz sized φ30×1 mm in Thickness

In the example 1, the processes in steps S10 to S17 were actually performed according to the flowchart illustrated in FIG. 5. This example 1 resulted as illustrated in a table 1. In the table 1, the cumulative input power was used as an index of the consumption amount of the target 141. The table 1 indicates Vc measured in step S12, Vq measured in step S15, and the speed of the film formation onto each of the lens substrates W measured in step S16.

TABLE 1

| | | | | | | |
|---|---|---|---|---|---|---|
| Cumulative | 2.64 | 2.84 | 6.10 | 17.7 | 32.3 | 66.9 |
| Input Power | | | | | | |
| [kWh] | | | | | | |
| Vc [V] | 202.5 | 200.0 | 202.7 | 194.7 | 203.8 | 201.1 |
| Vq [V] | 237.9 | 238.0 | 235.7 | 236.4 | 235.7 | 235.5 |
| Film Formation | 2.080 | 2.080 | 2.006 | 2.075 | 2.027 | 2.010 |
| Speed [nm/sec] | | | | | | |

The function F was acquired in step S18 in the flowchart illustrated in FIG. 5 from these experiment results with use of the equation (2), and was generated as indicated by the following equation (3).

$$F ( Vc , Vq ) = rateq = \frac{1}{Vq} \{ ( - 24.31 + 5506 ) Vc \text{/} Vq - 5763 + 26.44 Vq \} \qquad ( 3 )$$

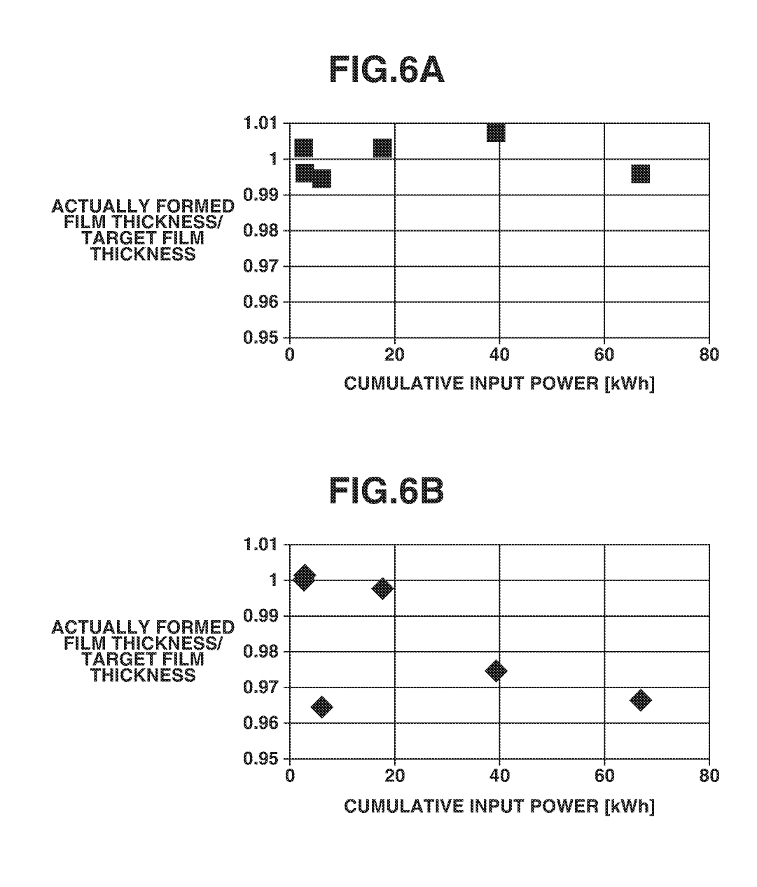

Next, a silicon dioxide film was formed with the target film thickness TH* thereof set to 320 nm according to the flowchart illustrated in FIG. 4 with use of the equation F expressed by this equation (3). A ratio between the target film thickness TH* and the actually formed film thickness since an initial state of the target 141 until the cumulative input power increased and the consumption amount of the target 141 increased was recorded as indicated in FIG. 6A.

### Comparative Example 1

In a comparative example 1, a silicon dioxide film was formed with use of the PEM control without the film thickness TH estimated with use of the equation (1) according to the example 1. The ratio between the target film thickness TH* and the actually formed film thickness since the initial state of the target 141 until the cumulative input power increased and the consumption amount of the target 141 increased was recorded as indicated in FIG. 6B.

### (Evaluation)

In the example 1, an error from the target film thickness TH* was 1% or lower over a wide range from the initial state of the target 141 to the state in which the target 141 was consumed by a large amount, as illustrated in FIG. 6A. Therefore, it was revealed that the example 1 was able to form the film with a small error from the target film thickness TH* and excellent reproducibility.

The comparative example 1 created an error of up to approximately 4% as the error from the target film thickness TH*, and failed to form the film with excellent reproducibility, as illustrated in FIG. 6B.

According to the example 1 and the comparative example 1, the function F, which is the predetermined function D1 in which the above-described output of the power source 145 in the compound mode and the above-described output of the power source 145 in the transition mode, and the film formation speed are associated with each other, was able to be acquired by conducting the experiment in advance. The use of the equation F expressed by the above-described equation (1) allowed the film formation speed in the transition mode to be correctly calculated and thus allowed the film formation to be carried out with the small error from the target film thickness TH* and the excellent reproducibility of the film thickness, even when the film formation was continuously carried out on a large number of film formation objects over a long period of time.

### Other Exemplary Embodiments

The present disclosure is not limited to the above-described exemplary embodiment, and can be modified in a large number of manners within the technical concept of the present disclosure. Further, the beneficial effects described in the exemplary embodiment only indicate an enumeration of most representative beneficial effects brought about from the present disclosure, and the beneficial effects of the present disclosure are not limited to those described in the exemplary embodiment.

The first exemplary embodiment has been described assuming that the intensity I of the light in the PEM control by the CPU 251 is expressed by the intensity ratio I_{Si}/I_{Ar} between the intensity I_{Si} of the light emitted from the material of the target 141 and the intensity I_{Ar} of the light emitted from the inert gas, but is not limited thereto. The first exemplary embodiment may also be realized, for example, when the intensity I is expressed with use of only the intensity I_{Si} of the light emitted from the material of the target 141 or when the intensity I is expressed with use of only the intensity I_{Ar} of the light emitted from the inert gas.

Further, the first exemplary embodiment has been described assuming that the CPU 251 controls the flow rate Q_{O2} of the reactive gas as the feedback control by the control unit, but is not limited to this feedback control. The first exemplary embodiment may also be realized, for example, when the control unit controls only the flow rate Q_{Ar} of the inert gas or when the control unit controls both the flow rate Q_{Ar} of the inert gas and the flow rate Q_{O2} of the reactive gas. Further, the first exemplary embodiment may also be realized when the control unit controls the flow rate Q_{O2} of the reactive gas and the output of the power source 145, when the control unit controls the flow rate Q_{O2} of the inert gas and the output of the power source 145, or when the control unit controls the flow rate Q_{Ar} of the inert gas, the flow rate Q_{O2} of the reactive gas, and the output of the power source 145. In other words, the control unit may perform the feedback control in any manner as long as it controls at least one of the flow rate Q_{O2} of the reactive gas and the flow rate Q_{Ar} of the inert gas in such a manner that the estimated film formation speed R approaches the target film formation speed.

The first exemplary embodiment has been described assuming that the output power of the power source 145 is controlled as the control of the output of the power source 145, but is not limited thereto. The first exemplary embodiment may also be realized, for example, when the output voltage V of the power source 145 is controlled, when the output current of the power source 145 is controlled, when the output voltage V and the output current of the power source 145 are controlled, when the output voltage V and the output power of the power source 145 are controlled, or when the output current and the output power of the power source 145 are controlled. In other words, the output of the power source 145 may be controlled in any manner as long as at least one of the output voltage V, the output current, and the output power is controlled.

The first exemplary embodiment has been described assuming that the predetermined function D1 is the equation, but is not limited thereto. For example, the predetermined function D1 may be a table. Further, the above-described exemplary embodiment has been described assuming that the predetermined function D1 is the function in which the output voltage Vc of the power source 145 in the compound mode and the output voltage Vq of the power source 145 in the transition mode, and the film formation speed in the transition mode are associated with each other, but is not limited thereto. The first exemplary embodiment may also be realized when any of the voltage V, the current, and the power is used as the output of the power source 145, and the film formation speed may be the film formation speed in the compound mode.

The first exemplary embodiment has been described assuming that Si is used as the target 141, but the target 141 is not limited to Si and various kinds of metal can be used therefor. Examples of the materials usable as the target 141 include niobium (Nb), yttrium (Y), tin (Sn), indium (In), zinc (Zn), titanium (Ti), thorium (Th), vanadium (V), tantalum (Ta), molybdenum (Mo), tungsten (W), copper (Cu), chromium (Cr), manganese (Mn), iron (Fe), nickel (Ni), cobalt (Co), samarium (Sm), praseodymium (Pr), and bismuth (Bi).

The first exemplary embodiment has been described assuming that the O₂ gas is used as the reactive gas, but the reactive gas is not limited to the O₂ gas and various kinds of reactive gas can be used therefor. Examples of the gas usable as the reactive gas include nitrogen (N₂), ozone (O₃), and carbon dioxide (CO₂) gas.

The first exemplary embodiment has been described assuming that the Ar gas is used as the inert gas serving as a carrier gas, but the inert gas is not limited to the Ar gas and various kinds of inert gas can be used therefor. Examples of the gas usable as the inert gas include helium (He), neon (Ne), krypton (Kr), xenon (Xe), and radon (Rn) gas.

The first exemplary embodiment has been described assuming that the sputtering apparatus 100 is the DC magnetron sputtering apparatus, but is not limited thereto. The first exemplary embodiment can be applied to various types of sputtering apparatuses, such as the DC sputtering apparatus, a radio frequency (RF) sputtering apparatus, and an RF magnetron sputtering apparatus.

The first exemplary embodiment has been described assuming that the storage unit is the HDD 254, but is not limited thereto. The storage unit may be any storage device, such as a universal serial bus (USB) memory, a memory card, and a solid state drive (SSD). Further, the storage unit is not limited to the storage device built in the controller 200, and may also be a storage device provided outside the controller 200.

In another exemplary embodiment, the period per which the output of the power source 145 in the compound mode is acquired can be set to a longer period than the period per which the output of the power source 145 in the transition mode is acquired. This setting can lead to a reduction in the number of times that the output of the power source 145 in the compound mode is acquired, thereby contributing to improvement of production efficiency.

The present disclosure can also be embodied by processing that supplies a program realizing one or more function(s) of the above-described exemplary embodiment to a system or an apparatus via a network or a storage medium, and causes one or more processor(s) in a computer of this system or apparatus to read out and execute the program. Further, the present disclosure can also be embodied by a circuit (for example, an application specific integrated circuit (ASIC)) realizing one or more function(s).

According to the aspect of the embodiments, the film having the desired film thickness can be manufactured with the excellent reproducibility regardless of, for example, the consumption amount of the target.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2017-223897, filed Nov. 21, 2017, which is hereby incorporated by reference herein in its entirety.

What is claimed is:

1. An apparatus comprising:
a chamber configured such that a film formation object and a target are disposed therein;
a reactive gas supply unit configured to supply reactive gas into the chamber;
an inert gas supply unit configured to supply inert gas into the chamber;
a power source configured to supply power to the target to generate plasma inside the chamber to cause an ion of the inert gas in the plasma to collide with the target;
a light reception unit configured to receive light emitted from the plasma; and
a control unit configured to control at least one of a flow rate of the reactive gas and a flow rate of the inert gas such that an intensity of the light approaches a target light intensity with use of a predetermined function in which an output of the power source in a compound mode and an output of the power source in a transition mode, and a film formation speed are associated with each other.

2. The apparatus according to claim 1, wherein the predetermined function is a quadratic or lower-order function of the output of the power source in the compound mode, the output of the power source in the transition mode, and a ratio of the output of the power source in the compound mode and the output of the power source in the transition mode.

3. The apparatus according to claim 1, further comprising a calculation unit configured to calculate an estimated film formation speed,
wherein the control unit periodically acquires the calculated estimated film formation speed and sets the target light intensity corresponding to the film formation speed.

4. The apparatus according to claim 1, further comprising a calculation unit configured to calculate an estimated film formation speed,
wherein the control unit estimates a film thickness by periodically acquiring the calculated estimated film formation speed, and forms a film in the transition mode until the film thickness reaches a target film thickness.

5. The apparatus according to claim 1, wherein a period per which the output of the power source in the compound mode is acquired is longer than a period per which the output of the power source in the transition mode is acquired.

6. The apparatus according to claim 1, wherein the predetermined function is a table generated based on an experiment or a simulation conducted in advance.

7. The apparatus according to claim 1, wherein the predetermined function is an equation generated based on an experiment or a simulation conducted in advance.

8. A method comprising:
disposing a film formation object and a target by using a chamber;
supplying reactive gas and inert gas into the chamber;
supplying power, from a power source, to a target to generate plasma inside the chamber to cause an ion of the inert gas in the plasma to collide with the target;
receiving light emitted from the plasma; and
controlling at least one of a flow rate of the reactive gas and a flow rate of the inert gas such that an intensity of the light approaches a target light intensity,
wherein the target light intensity is set with use of a predetermined function in which an output of the power source in a compound mode and an output of the power source in a transition mode, and a film formation speed are associated with each other.

9. The method according to claim 8, wherein the predetermined function is a quadratic or lower-order function of the output of the power source in the compound mode, the output of the power source in the transition mode, and a ratio of the output of the power source in the compound mode and the output of the power source in the transition mode.

10. The method according to claim 8, wherein the controlling includes periodically acquiring an estimated film formation speed, and setting the target light intensity corresponding to the film formation speed.

11. The method according to claim 8, wherein, in the controlling, a film thickness is estimated by periodically acquiring an estimated film formation speed, and a film is formed in the transition mode until the film thickness reaches a target film thickness.

12. The method according to claim 8, wherein a period per which the output of the power source in the compound mode is acquired is longer than a period per which the output of the power source in the transition mode is acquired.

13. The method according to claim 8, wherein the predetermined function is a table generated based on an experiment or a simulation conducted in advance.

14. The method according to claim 8, wherein the predetermined function is an equation generated based on an experiment or a simulation conducted in advance.
